(19) United States
(12) Patent Application Publication
(10) Pub. No.: US 2021/0153332 A1
(43) Pub. Date: May 20, 2021

(54) DROPLET GENERATOR AND EXTREME ULTRAVIOLET EXPOSURE DEVICE INCLUDING THE SAME

(71) Applicant: SAMSUNG ELECTRONICS CO., LTD., Suwon-si (KR)

(72) Inventors: Injae LEE, Seoul (KR); Sunghyup KIM, Hwaseong-si (KR); Jeonggil KIM, Hwaseong-si (KR); Jinyong KIM, Yongin-si (KR); Hyuck SHIN, Bucheon-si (KR); Sungho JANG, Hwaseong-si (KR); Inho CHOI, Seoul (KR)

(21) Appl. No.: 16/990,059

(22) Filed: Aug. 11, 2020

(30) Foreign Application Priority Data
Nov. 18, 2019 (KR) 10-2019-0147451

(51) Int. Cl. H05G 2/00; G03F 7/20

(52) U.S. Cl. CPC H05G 2/006; H05G 2/008; G03F 7/7055; G03F 7/70033

(57) ABSTRACT

A droplet generator for extreme ultraviolet (EUV) exposure device includes a nozzle body with an inclined portion, the nozzle body with the inclined portion having a nozzle shape to discharge a target material in a liquid state, a gas supply pipe, at least a portion of the gas supply pipe being in an internal space of the nozzle body and of the inclined portion, and the gas supply pipe to discharge gas toward the target material in the liquid state, a target material supply unit connected to the nozzle body, the target material supply unit including a first valve, a gas supply unit connected to the gas supply pipe, the gas supply unit including a second valve, and a control unit connected to the first and second valves to control a supply amount of the target material and the gas.

### CROSS-REFERENCE TO RELATED APPLICATION

Korean Patent Application No. 10-2019-0147451, filed on Nov. 18, 2019, in the Korean Intellectual Property Office, and entitled: “Droplet Generator for EUV,” is incorporated by reference herein in its entirety.

### BACKGROUND

### 1. Field

The present disclosure relates to a droplet generator for an extreme ultraviolet (EUV) exposure device.

### 2. Description of the Related Art

In general, an extreme ultraviolet (EUV) exposure device, e.g., an EUV lithography device, generates an EUV light by irradiating light, e.g., a laser beam, toward a target material, e.g., liquid tin, to generate plasma, which emits EUV light. The target material, e.g., liquid tin, may be released through a nozzle, e.g., in a form of droplets.

### SUMMARY

According to an aspect of the present disclosure, a droplet generator for extreme ultraviolet (EUV) exposure device includes a nozzle body with an inclined portion, the nozzle body with the inclined portion having a nozzle shape to discharge a target material in a liquid state, a gas supply pipe, at least a portion of the gas supply pipe being in an internal space of the nozzle body and of the inclined portion, and the gas supply pipe to discharge gas toward the target material in the liquid state, a target material supply unit connected to the nozzle body, the target material supply unit including a first valve, a gas supply unit connected to the gas supply pipe, the gas supply unit including a second valve, and a control unit connected to the first and second valves to control a supply amount of the target material and the gas.

According to another aspect of the present disclosure, an extreme ultraviolet (EUV) exposure device includes a light source system to generate exposure light, the light source system including a droplet generator to generate a droplet of a target material, the droplet generator having a nozzle body with an inclined portion, the nozzle body with the inclined portion having a nozzle shape to discharge the droplet of the target material in a liquid state, and a gas supply pipe, at least a portion of the gas supply pipe being in an internal space of the nozzle body and of the inclined portion, and the gas supply pipe to discharge gas toward the target material in the liquid state, a light source to emit light to be incident on the target material supplied by the droplet generator, a collector to collect and reflect plasma generated by the laser light source and the target material, and a source container spaced apart from the collector, an illumination optical system to adjust and transmit the exposure light generated by the light source system, a mask system to pattern the exposure light transmitted from the illumination optical system, a substrate system, and a chamber to accommodate the light source system, the illumination optical system, the mask system, and the substrate system, the chamber being connected to a vacuum pump.

### BRIEF DESCRIPTION OF THE DRAWINGS

Features will become apparent to those of skill in the art by describing in detail exemplary embodiments with reference to the attached drawings, in which:

FIG. 1 is a schematic diagram illustrating an extreme ultraviolet (EUV) exposure device according to example embodiments;

FIG. 2 is a schematic diagram illustrating a droplet generator in an EUV exposure device according to example embodiments;

FIG. 3 is a configuration diagram illustrating a portion of a nozzle body and a gas supply pipe of a droplet generator according to example embodiments;

FIGS. 4 to 7 are explanatory diagrams illustrating stages in a method of discharging a target material from a droplet generator of an EUV exposure device according to example embodiments;

FIG. 8 is an explanatory diagram illustrating a target discharged from a droplet generator of an EUV exposure device according to example embodiments relative to comparative art;

FIG. 9 is a graph illustrating thicknesses according to diameters of a target material discharged from the droplet generator according to example embodiments relative to comparative art;

FIG. 10 is a configuration diagram illustrating a portion of a nozzle body and a gas supply pipe of a droplet generator according to example embodiments;

FIG. 11 is a configuration diagram illustrating a portion of a nozzle body and a gas supply pipe of a droplet generator according to example embodiments;

FIG. 12 is an explanatory diagram for describing a target material discharged from the droplet generator in FIG. 11;

FIG. 13 is a configuration diagram illustrating a portion of a nozzle body and a gas supply pipe of a droplet generator according to example embodiments; and

FIG. 14 is a configuration diagram illustrating a portion of a nozzle body and a gas supply pipe of a droplet generator according to example embodiments.

### DETAILED DESCRIPTION

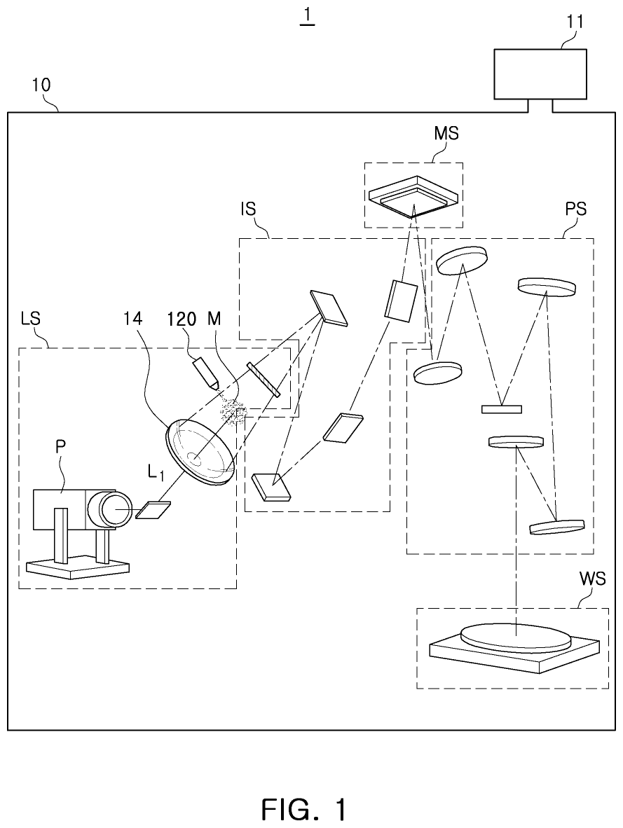

FIG. 1 is a schematic diagram of an extreme ultraviolet (EUV) exposure device according to example embodiments.

Referring to FIG. 1, an EUV exposure device 1, e.g., an EUV lithography device, may include a light source system LS for generating exposure light, an optical system for adjusting and patterning the exposure light generated by the light source system LS, and a substrate system WS. The optical system may include an illumination optical system IS for transmitting the exposure light generated by the light source system LS, a mask system MS for patterning the exposure light transmitted from the illumination optical system IS, and a projection optical system PS for transmitting the light patterned by the mask system MS onto the substrate system WS.

As illustrated in FIG. 1, the light source system LS, the illumination optical system IS, the mask system MS, the projection optical system PS, and the substrate system WS may be accommodated in a chamber 10 that isolates them from an outside. A vacuum pump may be connected to the chamber 10, and a molecular oxygen supply device 11 may be connected to the chamber 10.

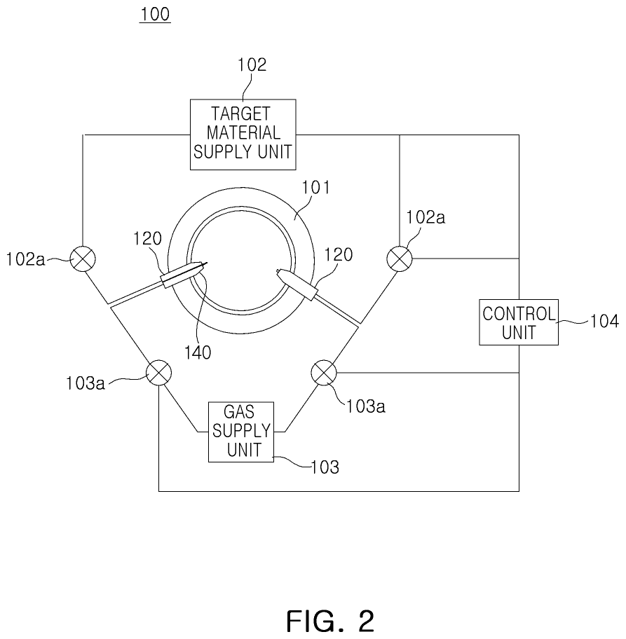

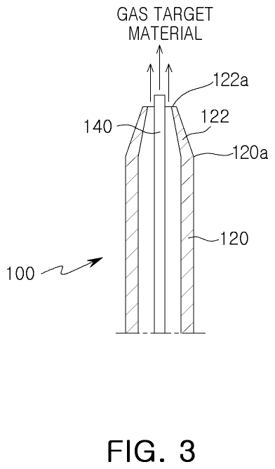

The light source system LS may include a light source P, a collector 14, and a droplet generator with a nozzle body 120. The light source system LS may generate EUV exposure light by collecting and reflecting a high-temperature plasma beam generated by irradiating from the light source P laser light Li having a high-intensity pulse to a target material M sprayed from the nozzle body 120. The nozzle body 120 may dispose drops of the target material M, e.g., tin drops, such that pulses of the laser light Li hitting the target material M produce plasma that emits the EUV exposure light toward the illumination optical system IS. The droplet generator with the nozzle body 120 will be described in more detail below with reference to FIGS. 2-3.

FIG. 2 is a schematic diagram of a droplet generator in the EUV exposure device 1 according to example embodiments. FIG. 3 is a configuration diagram of a portion of the nozzle body 120 in the droplet generator of FIG. 2.

As illustrated in FIG. 2, a droplet generator 100, i.e., a target generator, may include a target material supply unit 102, a gas supply unit 103, the nozzle body 120, a gas supply pipe 140, and a control unit 104. The target material supply unit 102 may be provided with a first valve 102a, and the gas supply unit 103 may be provided with a second valve 103a. The control unit 104 may be connected to the first and second valves 102a and 103a.

Referring to FIG. 2, a plurality of droplet generators 100, i.e., target generators, may be disposed in each EUV exposure device 1. As illustrated in FIG. 2, a plurality of nozzle bodies 120 may be positioned in each droplet generator 100 to be spaced apart from each other in a source container 101. For example, two nozzle bodies 120 may be spaced apart from each other in the source container 101, which is disposed in the EUV exposure device 1. However, the present disclosure is not limited thereto, e.g., only one nozzle body 120 or more than two nozzle bodies 120 may be installed in the source container 101 of the EUV exposure device 1.

As illustrated in FIG. 3, the nozzle body 120 may have a tubular shape such that a target in a liquid state may flow, e.g., the nozzle body 120 may have a shape of a hollow cylinder, and an inclined portion 122 may be provided at a front-end 120a of the nozzle body 120. For example, as illustrated in FIG. 3, the inclined portion 122 may extend, e.g., continuously and integrally, from the front-end 120a of the nozzle body 120 to have a gradually decreasing width between the front-end 120a and an opening 122a. For example, as illustrated in FIG. 1, the front-end of the nozzle body 120 may be at an end of the nozzle body 120 facing toward a light path of the laser light Li. That is, the structure of the nozzle body 120 with the inclined portion 122 may have a nozzle shape, e.g., a structure having a decreasing cross-section, in which a width thereof is narrowed toward the front-end thereof, e.g., toward the opening 122a. The nozzle body 120 may be connected to the target material supply unit 102, as illustrated in FIG. 2, to which a target material in a liquid state, e.g., tin, is supplied. The target material supply unit 102 may be provided with the first valve 102a to supply a predetermined amount of droplets into the nozzle body 120 to be released through the opening 122a.

As further illustrated in FIG. 3, the gas supply pipe 140 may be disposed in an internal space of the nozzle body 120, and an end of the gas supply pipe 140 may be disposed to protrude from the inclined portion 122 of the nozzle body 120. For example, as illustrated in FIG. 3, the gas supply pipe 140 may extend through a center of the nozzle body 120, e.g., to be concentric and coaxial with the nozzle body 120, and an end of the gas supply pipe 140 may extend beyond a terminal end of the inclined portion 122 to protrude outside the inclined portion 122. For example, as illustrated in FIG. 3, a width of the gas supply pipe 140 may be smaller than a width of the nozzle body 120, so the target material may be filled in an internal space of the nozzle body 120 to surround the gas supply pipe 140. As an example, the gas supply pipe 140 may be introduced into the nozzle body 120 from the end of the nozzle body 120. Meanwhile, the gas supply pipe 140 may be disposed in a central portion of the nozzle body 120. That is, the target material in the liquid state, e.g., tin, may be discharged from the nozzle body 120 to the outside through, e.g., around the protruding edge of, the gas supply pipe 140.

The gas supply pipe 140 may accommodate gas to be discharged through the protruding edge of the gas supply pipe 140. The discharged gas may be an inert gas, e.g., nitrogen gas. However, the present disclosure is not limited thereto, and the gas discharged through the gas supply pipe 140 is not limited to an inert gas. As illustrated in FIG. 2, the gas supply pipe 140 may be connected to the gas supply unit 103, which may be provided with the second valve 103a to supply gas corresponding to a predetermined amount of droplets.

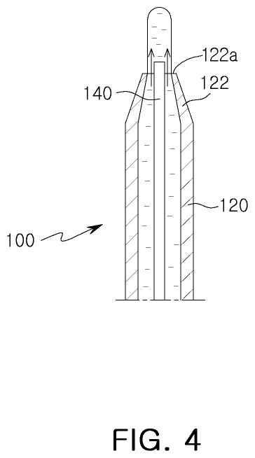

Referring back to FIG. 2, the control unit 104 may be connected to the first and second valves 102a and 103a provided in the target material supply unit 102 and the gas supply unit 103. The control unit 104 may control the first and second valves 102a and 103a to supply amounts of material and gas, respectively, corresponding to an amount of droplets to be released from the nozzle body 120. Discharge of droplets through the nozzle body 120 will be described in detail with reference to FIGS. 4-7.

Referring to FIGS. 4 to 7, the target material in the liquid state, e.g., tin, and the gas, e.g., inert gas, may be respectively supplied into the nozzle body 120 and the gas supply pipe 140 of the droplet generator 100.

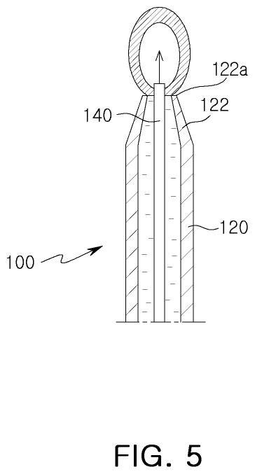

For example, as illustrated in FIG. 4, the target material in the liquid state, e.g., tin, is first supplied through the nozzle body 120 (e.g., the target material fills an interior of the nozzle body 120 around the gas supply pipe 140 to extend outside through the inclined portion 122 and the opening 122a). Subsequently, as shown in FIG. 5, the gas may be supplied through the gas supply pipe 140, together with the target material in the liquid state, e.g., tin, through the nozzle body 120, e.g., the gas may be discharged through the edge of the gas supply pipe 140 together with the liquid discharge through the opening 122a. As shown in FIGS. 4-5, when the liquid target material begins gathering outside the opening 122a to form a drop (FIG. 4), the gas is discharged into, e.g., the center of, the liquid target material outside the opening 122a (white oval in FIG. 5). Accordingly, the target material in the liquid state, e.g., tin, may have a hollow droplet drop shape, i.e., a bubble shape.

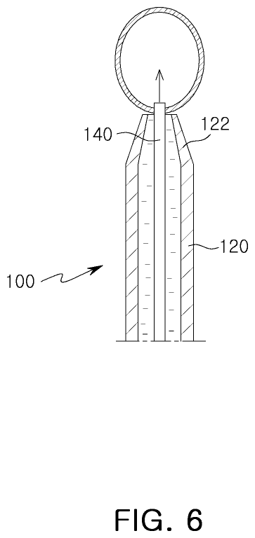

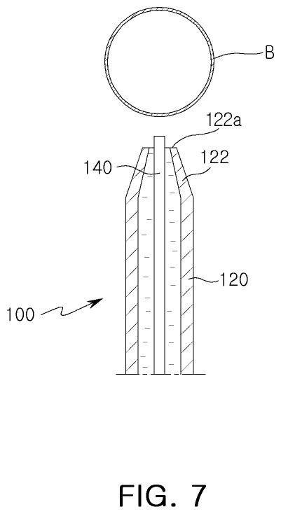

Thereafter, as shown in FIGS. 6 and 7, the target material in the liquid state, e.g., tin, may gradually have reduced thickness of droplets and have a spherical bubble shape. That is, referring to FIG. 6, the discharged gas may gradually expand within the discharged target material to spread, e.g., increase a size of, the target material outside the opening, until a substantially spherical bubble B (i.e., drop B) is formed and is separated from the opening 122a (FIG. 7), e.g., the resultant drop B may be hollow inside and have a larger surface area due to the expanding gas inside.

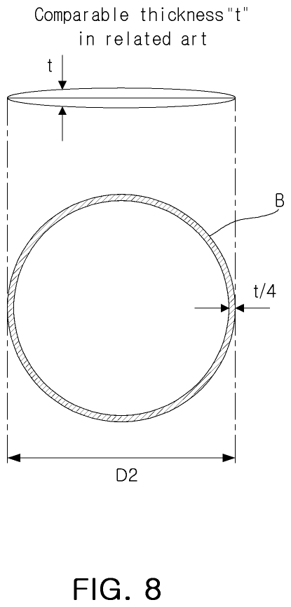

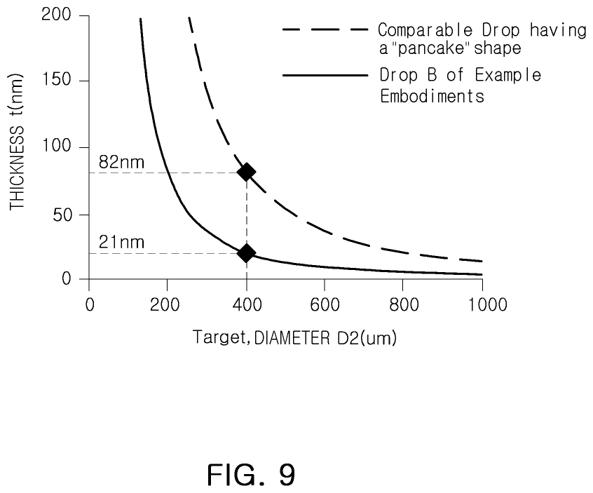

As shown in FIGS. 8 and 9, the thickness of the target material in the formed drop B may be reduced, e.g., to about a fourth of comparable drops released without the gas supply pipe 140, due to the expanding gas from its interior. That is, it can be seen that when a diameter of the drop B discharged by the droplet generator 100 is D2, its thickness is approximately t/4, e.g., as compared to a comparable drop with a same diameter D2 having a thickness t.

As a result, when the droplet generator 100 according to embodiments is used, the surface area of the droplet is increased, e.g., without using pre-pulse, thereby increasing a reaction between the target material and laser pulse to trigger EUV light generation. As such, a reaction by plasma may be improved. Further, since a position control of the target may be facilitated by not using pre-pulse, it is possible to prevent or substantially suppress occurrence of contamination by residues, and the like.

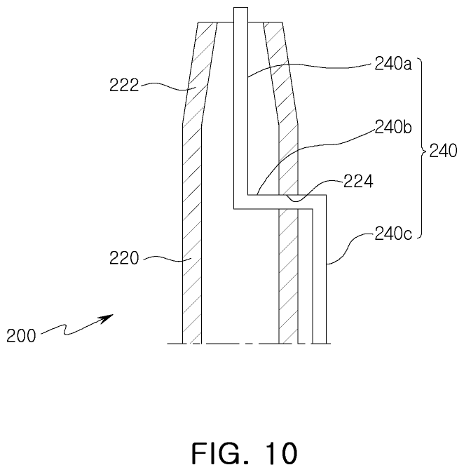

FIG. 10 is a schematic configuration diagram illustrating a portion of a nozzle body and a gas supply pipe of a droplet generator for an EUV exposure device according to example embodiments.

Referring to FIG. 10, a droplet generator 200 for an EUV exposure device may include a nozzle body 220 and a gas supply pipe 240. The nozzle body 220 with an inclined portion 222 at its front-end may be substantially the same as the nozzle body 120 and the inclined portion 122 described previously with reference to FIG. 3, with an exception of a through-hole 224.

In detail, the nozzle body 220 may have a tubular shape such that a target material in a liquid state, e.g., tin, may flow. The inclined portion 222 may be provided at a front-end of the nozzle body 220. That is, the nozzle body 220 may have a nozzle shape in which a width thereof is narrowed toward the front-end. The nozzle body 220 may be connected to a target material supply unit to which a target material in a liquid state, e.g., tin, is supplied. The target material supply unit may be provided with a first valve to supply a predetermined amount of droplets. The nozzle body 220 may be provided with the through-hole 224 disposed to be adjacent to the inclined portion 222. The through-hole 224 may provide a path through which the gas supply pipe 240 is inserted into the nozzle body 220.

As illustrated in FIG. 10, the gas supply pipe 240 may include a first portion 240a, a second portion 240b, and a third portion 240c. For example, as further illustrated in FIG. 10, the second portion 240b may be connected between the first and third portions 240a and 240c in a step shape, e.g., the second portion 240b may be substantially perpendicular to each of the first and third portions 240a and 240c. The first portion 240a of the gas supply pipe 240 may be a front-end portion disposed in an internal space of the nozzle body 220, and may protrude outside from the inclined portion 222 of the nozzle body 220. The third portion 240c of the gas supply pipe 240 may extend outside the nozzle body 220 to be connected to a gas supply unit, while the second portion 240b of the gas supply pipe 240 may extend from the third portion 240c to the first portion 240a through the through-hole 224. As such, the gas supply pipe 240 may be introduced into the nozzle body 220 through the through-hole 224 disposed at the front-end of the nozzle body 220. As illustrated in FIG. 10, a front-end of the gas supply pipe 240 may be disposed in a central portion of the nozzle body 220, e.g., the first portion 240a of the gas supply pipe 240 may be concentric and coaxial with the nozzle body 220 and the inclined portion 222. That is, the target material in the liquid state, e.g., tin, may be discharged from the nozzle body 220 to the outside through the gas supply pipe 240.

For example, gas discharged through the gas supply pipe 240 may be an inert gas, e.g., nitrogen gas. However, the present disclosure is not limited thereto, and the gas discharged through the gas supply pipe 240 is not limited to the inert gas.

The gas supply pipe 240 may be connected to a gas supply unit. The gas supply pipe 240 may be provided with a second valve to supply gas corresponding to a predetermined amount of droplets. Furthermore, as described previously with reference to FIGS. 2-3, the first and second valves provided in the target material supply unit and the gas supply unit may be connected to a control unit. The control unit may control the first and second valves to supply an amount of gas corresponding to an amount of droplets.

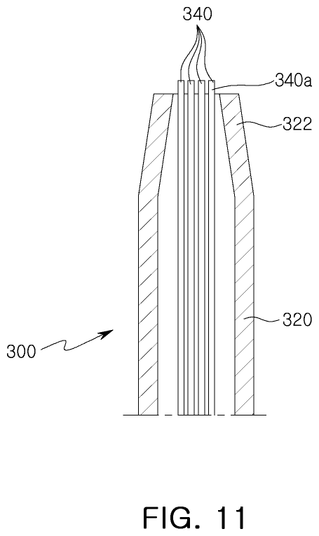

FIG. 11 is a schematic configuration diagram illustrating a portion of a nozzle body and a gas supply pipe of a droplet generator for an EUV exposure device according to example embodiments.

Referring to FIG. 11, a droplet generator 300 for an EUV exposure device may include a nozzle body 320 and a gas supply pipe 340. The nozzle body 320 with an inclined portion 322 at its front-end may be substantially the same as the nozzle body 120 and the inclined portion 122 described previously with reference to FIG. 3.

In detail, the nozzle body 320 may have a tubular shape such that a target material in a liquid state, e.g., tin, may flow. The inclined portion 322 may be provided at the front-end of the nozzle body 320. That is, the nozzle body 320 may have a nozzle shape in which a width thereof is narrowed toward the end. The nozzle body 320 may be connected to a target material supply unit to which a target material in a liquid state, e.g., tin, is supplied. The target material supply unit may be provided with a first valve to supply a predetermined amount of droplets.

The gas supply pipe 340 may be disposed in an internal space of the nozzle body 320, and the end thereof may be disposed to protrude from the inclined portion 322 of the nozzle body 320. As an example, the gas supply pipe 340 may be introduced into the nozzle body 320 from the end of the nozzle body 320. Meanwhile, the gas supply pipe 340 may be disposed in a central portion of the nozzle body 320, e.g., the gas supply pipe 340 may be concentric and coaxial with the nozzle body and the inclined portion 322. That is, the target material in the liquid state, e.g., tin, may be discharged from the nozzle body 320 to the outside through the gas supply pipe 340.

As illustrated in FIG. 11, the gas supply pipe 340 may include a plurality of gas supply channels 340a. As an example, four gas supply channels 340a may be disposed in a central portion of the nozzle body 320. For example, as illustrated in FIG. 11, the four gas supply channels 340a may be parallel to each other and extend along the nozzle body 320 and the inclined portion 322. For example, as further illustrated in FIG. 1, the four gas supply channels 340a may be centered in the nozzle body 320 and the inclined portion 322, e.g., edges of all of the four gas supply channels 340a may extend out of the inclined portion 322. However, the present disclosure is not limited thereto, and any convenient number of gas supply channels 340a may be provided.

Gas discharged through the gas supply channels 340a may be inert gas, e.g., nitrogen gas. However, the present disclosure is not limited thereto, e.g., the gas discharged through the gas supply pipe 340 may be any convenient gas.

The gas supply pipe 340 may be connected to a gas supply unit. The gas supply unit may be provided with a second valve to supply gas corresponding to a predetermined amount of droplets. Furthermore, as described previously with reference to FIGS. 2-3, the first and second valves provided in the target material supply unit and the gas supply unit may be connected to a control unit. The control unit may control the first and second valves to supply an amount of gas corresponding to the amount of droplets.

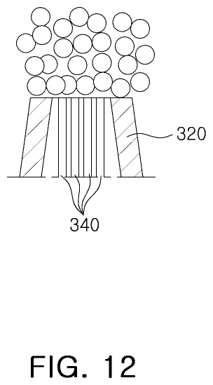

It is noted, as illustrated in FIG. 12, that the droplets discharged by the droplet generator 300 for an EUV exposure device of FIG. 11 may have a plurality of small bubble shapes.

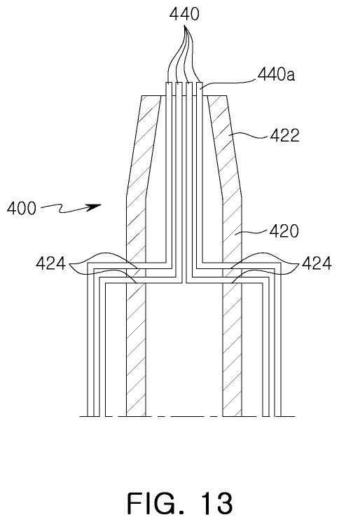

FIG. 13 is a schematic configuration diagram illustrating a portion of a nozzle body and a gas supply pipe of a droplet generator for an EUV exposure device according to example embodiments.

Referring to FIG. 13, a droplet generator 400 for an EUV exposure device may include a nozzle body 420 and a gas supply pipe 440. The nozzle body 420 with an inclined portion 422 at its front-end may be substantially the same as the nozzle body 120 and the inclined portion 122 described previously with reference to FIG. 3, with an exception of a plurality of through-holes 424.

In detail, the nozzle body 420 may have a tubular shape such that a target material in a liquid state, e.g., tin, may flow. The inclined portion 422 may be provided at the front-end of the nozzle body 420. That is, the nozzle body 420 may have a nozzle shape that becomes narrower toward the end. A target material supply unit to which a target material in a liquid state, e.g., tin, is supplied, may be connected to the nozzle body 420. The target material supply unit may be provided with a first valve to supply a predetermined amount of droplets. The nozzle body 420 may be provided with a plurality of through-holes 424 disposed to be adjacent to the inclined portion 422. The through-hole 424 may provide a path through which the gas supply pipe 440 is inserted and introduced into the nozzle body 420.

For example, as illustrated in FIG. 13, the gas supply pipe 440 may include a plurality of gas supply channels 440a. For example, each of the gas supply channels 440a may have a structure similar to that described previously with reference to the gas supply pipe 240 in FIG. 10. For example, each of the gas supply channels 440a may have a front-end portion disposed in an internal space of the nozzle body 420, and may have an edge disposed to protrude from the inclined portion 422 of the nozzle body 420. For example, the gas supply channels 440a may be introduced into the nozzle body 420 through the plurality of through-holes 424, respectively, disposed at the front-end of the nozzle body 420. Meanwhile, the front-ends of the gas supply channels 440a may be disposed in a central portion of the nozzle body 420. That is, the target material in the liquid state, e.g., tin may be discharged from the nozzle body 420 to the outside through the gas supply channels 440a.

For example, four gas supply channels 440a may be provided. For example, the four front-ends of the gas supply channels 440a may be disposed in a central portion of the nozzle body 420 in an arrangement similar to that described previously with reference to FIG. 11. However, the present disclosure is not limited thereto, and any convenient number of gas supply channels 440a may be provided.

Gas discharged through the gas supply channels 440a may be inert gas, e.g., nitrogen gas. However, the present disclosure is not limited thereto, and the gas discharged through the gas supply channels 440a is not limited to the inert gas.

The gas supply pipe 440 may be connected to a gas supply unit. The gas supply unit may be provided with a second valve to supply gas corresponding to a predetermined amount of droplets. Furthermore, the first and second valves provided in the target material supply unit and the gas supply unit may be connected to a control unit. The control unit may control the first and second valves to supply an amount of gas corresponding to the amount of droplets.

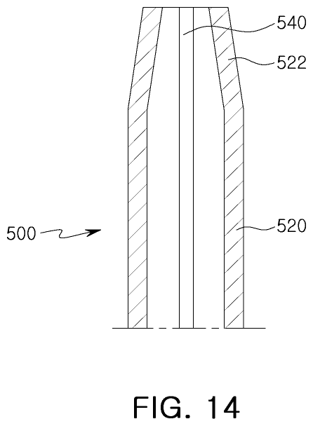

FIG. 14 is a schematic configuration diagram illustrating a portion of a nozzle body and a gas supply pipe of a droplet generator for an EUV exposure device according to example embodiments.

Referring to FIG. 14, a droplet generator 500 for an EUV exposure device may include a nozzle body 520 and a gas supply pipe 540. The nozzle body 520 with an inclined portion 522 at its front-end may be substantially the same as the nozzle body 120 and the inclined portion 122 described previously with reference to FIG. 3.

In detail, the nozzle body 520 may have a tubular shape such that a target material in a liquid state, e.g., tin, may flow. The inclined portion 522 may be provided at the front-end of the nozzle body 520. That is, the nozzle body 520 may have a nozzle shape in which a width thereof is narrowed toward the end. A target material supply unit to which a target material in a liquid state, e.g., tin, is supplied may be connected to the nozzle body 520. The target material supply unit may be provided with a first valve to supply a predetermined amount of droplets.

The gas supply pipe 540 may be disposed in an inner space of the nozzle body 520, e.g., to be concentric and coaxial with the nozzle body 420 and the inclined portion 522. A front-end of the gas supply pipe 540 may be disposed to coincide with the end of the inclined portion 522 of the nozzle body 520, e.g., front ends of the gas supply pipe 540 and the inclined portion 522 may be aligned to be coplanar. As an example, the gas supply pipe 540 may be introduced into the nozzle body 520 from the end of the nozzle body 520. The gas supply pipe 540 may be disposed in a central portion of the nozzle body 520. That is, the target material in the liquid state, e.g., tin, may be discharged from the nozzle body 520 to the outside through the gas supply pipe 540.

In addition, gas discharged through the gas supply pipe 540 may be inert gas, e.g., nitrogen gas. However, the present disclosure is not limited thereto, and the gas discharged through the gas supply pipe 540 is not limited to the inert gas.

The gas supply pipe 540 may be connected to the gas supply unit. In addition, the gas supply unit may be provided with a second valve to supply gas corresponding to a predetermined amount of droplets. Furthermore, the first and second valves provided in the target material supply unit and the gas supply pipe may be connected to a control unit. The control unit may control the first and second valves to supply an amount of gas corresponding to the amount of droplets.

By way of summation and review, it is important to increase a surface area between the target material, e.g., droplets of tin, and the plasma to increase an amount of generated EUV light. For example, a double pulse method, e.g., use of a pre-pulse and a main-pulse, may be used. However, use of the pre-pulse may cause an error in a position and a size of the target material, e.g., droplets of tin, in a process of expanding the surface area of the target material, e.g., droplets of a tin from a size of several tens of to pancake-shaped having several hundreds of μm. As such, the error in the position and size of the target material may decrease the efficiency of switching to the EUV light source, and may contaminate a collector.

In contrast, an aspect of the present disclosure provides a droplet generator for an EUV exposure device, which can facilitate a position control of a target. In addition, an aspect of the present disclosure provide a droplet generator for an EUV exposure device that reduces contamination of a collector.

That is, as set forth above, a droplet generator for an EUV exposure device, according to example embodiments, includes a gas supply pipe within a nozzle body discharging target material, e.g., tin, in a liquid state, so that the gas can be supplied to the target material. Accordingly, the target material expands with the supplied gas to form a bubble shape. As such, the surface area of the resultant bubble shape is expanded, and by not using a pre-pulse, it is possible to provide a droplet generator for an EUV exposure device that can facilitate a position control of a target material. In addition, it is possible to provide a droplet generator for an EUV exposure device that can reduce contamination of a collector.

Example embodiments have been disclosed herein, and although specific terms are employed, they are used and are to be interpreted in a generic and descriptive sense only and not for purpose of limitation. In some instances, as would be apparent to one of ordinary skill in the art as of the filing of the present application, features, characteristics, and/or elements described in connection with a particular embodiment may be used singly or in combination with features, characteristics, and/or elements described in connection with other embodiments unless otherwise specifically indicated. Accordingly, it will be understood by those of skill in the art that various changes in form and details may be made without departing from the spirit and scope of the present invention as set forth in the following claims.

What is claimed is:

1. A droplet generator for extreme ultraviolet (EUV) exposure device, the droplet generator comprising:
a nozzle body with an inclined portion, the nozzle body with the inclined portion having a nozzle shape to discharge a target material in a liquid state;
a gas supply pipe, at least a portion of the gas supply pipe being in an internal space of the nozzle body and of the inclined portion, and the gas supply pipe to discharge gas toward the target material in the liquid state;
a target material supply unit connected to the nozzle body, the target material supply unit including a first valve;
a gas supply unit connected to the gas supply pipe, the gas supply unit including a second valve; and
a control unit connected to the first and second valves to control a supply amount of the target material and the gas.

2. The droplet generator as claimed in claim 1, wherein an edge of the gas supply pipe protrudes outside of the inclined portion, the inclined portion being between the nozzle body and the protruding edge of the gas supply pipe.

3. The droplet generator as claimed in claim 1, wherein the gas supply pipe is inserted into the nozzle body through a side surface of the nozzle body.

4. The droplet generator as claimed in claim 3, wherein an external portion of the gas supply pipe extends outside and parallel to the nozzle body, the gas supply unit being connected to the external portion of the gas supply pipe.

5. The droplet generator as claimed in claim 1, wherein the gas supply pipe includes a plurality of gas supply channels parallel to each other.

6. The droplet generator as claimed in claim 5, wherein front-ends of the plurality of gas supply channels protrude outside of the inclined portion.

7. The droplet generator as claimed in claim 6, wherein the plurality of gas supply channels are inserted into the nozzle body through a side surface of the nozzle body.

8. The droplet generator as claimed in claim 7, wherein external portions of the plurality of gas supply channels extend outside and parallel to the nozzle body, the gas supply unit being connected to the external portions of the plurality of gas supply channels.

9. The droplet generator as claimed in claim 1, wherein the gas supply pipe is concentric with each of the nozzle body and the inclined portion.

10. An EUV exposure, comprising:
a light source system to generate exposure light, the light source system including the droplet generator of claim 1;
an illumination optical system to transmit the exposure light generated by the light source system;
a mask system to pattern the exposure light transmitted from the illumination optical system;
a projection optical system to transmit the light patterned by the mask system onto a substrate system; and
a chamber to accommodate the light source system, the illumination optical system, the mask system, the projection optical system, and the substrate system, the chamber being connected to a vacuum pump.

11. An extreme ultraviolet (EUV) exposure device, comprising:
a light source system to generate exposure light, the light source system including:
a droplet generator to generate a droplet of a target material, the droplet generator having:
a nozzle body with an inclined portion, the nozzle body with the inclined portion having a nozzle shape to discharge the droplet of the target material in a liquid state, and
a gas supply pipe, at least a portion of the gas supply pipe being in an internal space of the nozzle body and of the inclined portion, and the gas supply pipe to discharge gas toward the target material in the liquid state;
a light source to emit light to be incident on the target material supplied by the droplet generator,
a collector to collect and reflect plasma generated by the laser light source and the target material, and
a source container spaced apart from the collector;
an illumination optical system to adjust and transmit the exposure light generated by the light source system;
a mask system to pattern the exposure light transmitted from the illumination optical system;
a substrate system; and
a chamber to accommodate the light source system, the illumination optical system, the mask system, and the substrate system, the chamber being connected to a vacuum pump.

12. The EUV exposure device as claimed in claim 11, wherein an edge of the gas supply pipe protrudes outside of the inclined portion, the inclined portion being between the nozzle body and the protruding edge of the gas supply pipe.

13. The EUV exposure device as claimed in claim 11, wherein an edge of the gas supply pipe is aligned with an edge of the inclined portion.

14. The EUV exposure device as claimed in claim 11, wherein the gas supply pipe is inserted into the nozzle body through a side surface of the nozzle body.

15. The EUV exposure device as claimed in claim 14, wherein an external portion of the gas supply pipe extends outside and parallel to the nozzle body, a gas supply unit being connected to the external portion of the gas supply pipe.

16. The EUV exposure device as claimed in claim 11, wherein the gas supply pipe includes a plurality of gas supply channels parallel to each other.

17. The EUV exposure device as claimed in claim 16, wherein front-ends of the plurality of gas supply channels protrude outside of the inclined portion.

18. The EUV exposure device as claimed in claim 17, wherein the plurality of gas supply channels are inserted into the nozzle body through a side surface of the nozzle body.

19. The EUV exposure device as claimed in claim 18, wherein external portions of the plurality of gas supply channels extend outside and parallel to the nozzle body, a gas supply unit being connected to the external portions of the plurality of gas supply channels.

20. The EUV exposure device as claimed in claim 11, further comprising:
a target material supply unit connected to the nozzle body, the target material supply unit including a first valve for adjusting an amount of the target material;
a gas supply unit connected to the gas supply pipe, the gas supply unit including a second valve for adjusting an amount of the gas; and
a control unit connected to the first and second valves to control the amount of the target material and the gas.
